(19) United States
(12) Patent Application Publication
(10) Pub. No.: US 2007/0037389 A1
(43) Pub. Date: Feb. 15, 2007

(54) METHOD FOR ELECTROLESS PLATING METAL CAP BARRIER ON COPPER

(76) Inventors: Shu-Jen Chen, Hsin-Chu City (TW); Chia-Lin Hsu, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/161,650

(22) Filed: Aug. 11, 2005

(51) Int. Cl. H01L 21/44

(52) U.S. Cl. 438/678

(57) ABSTRACT

A process for electroless plating a metal cap barrier on a substrate is disclosed. Copper metallization is formed on the substrate such that the substrate has an exposed top surface of a copper line. The exposed top surface of the copper line is pre-cleaned. The pre-cleaned exposed top surface of the copper line is exposed to an activation solution. The exposed top surface of the copper line of the substrate is then in-situ annealed in an vapor ambient containing a flow of alcohol and carrier gas at a temperature less than 400° C. The metal cap barrier is selectively deposited onto the exposed top surface of the copper line by performing electroless plating.

### BACKGROUND OF THE INVENTION

1. Field of the Invention

The present invention relates generally to the field of semiconductor fabrication and, more particularly to a method for electroless plating metal cap barrier such as CoWP or CoWB onto a reduced copper surface involving the use of an in-situ ethanol vapor annealing.

2. Description of the Prior Art

In the manufacture of integrated circuit devices, copper has replaced aluminum as the interconnect metal of choice due to its significantly lower resistivity. Recently, electrolessly deposited CoWP has been used as a metal cap barrier material to encapsulate copper lines. The presence of W in CoWP significantly enhances the barrier properties. Typically, the barrier cap layer is selectively deposited onto the exposed copper of the previously planarized surface.

One technique for selectively depositing such metal cap barrier on copper is electroless plating. Electroless plating includes chemically reducing metal ions in an electroless plating solution onto a conductive or non-conductive surface without supplying any electric current from the outside. Electroless plating can be accomplished either by immersion electroless systems or by spray electroless systems. In immersion electroless plating systems, the surface to be coated is immersed in the electrolyte bath. By comparison, the electrolyte solution is sprayed over the object in spray electroless plating systems.

In the process of electroless plating the metal cap barrier on copper, the poor corrosion resistance of copper is a major concern. Unlike other metal oxidation (such as aluminum oxidation), copper is readily oxidized to form Cu₂O and CuO at low temperatures (below 200° C.) and no self-protective oxide layer forms to prevent the copper from further oxidation. The electroless plating of the metal cap barrier is very sensitive to the copper surface cleanness. The oxidized copper (surface oxides) degrades the selectivity and yield of the electroless plating of the metal cap barrier.

Conventionally, the oxidized copper is removed from the top surface of the copper lines by subjecting the wafers to an ex-situ pre-clean bath containing chemicals to dissolve surface oxides and contaminations. One drawback of this is that the prior art pre-clean bath may not thoroughly remove the surface oxides. In addition, there is usually a span of time (also referred to as “Q-time”) for the pre-cleaned wafers to wait for the subsequent electroless plating for the metal cap barrier. During the Q-time, new oxidized copper may produce, thus adversely affecting the selective deposition of metal cap barrier.

In light of the above, there is a need in this industry to provide an electroless plating process for the selective deposition of barrier alloys over conductive layers without intermediate exposure of the substrate to air (minimum Q time).

### SUMMARY OF THE INVENTION

It is the primary object of the present invention to provide an improved method for electroless plating metal cap barrier such as CoWP or CoWB exclusively onto a freshly reduced copper surface in order to solve the above-mentioned prior art problems.

It is another object of the present invention to provide an electroless plating for the selective deposition of barrier alloys over conductive layers in combination with an in-situ ethanol vapor annealing.

According to the claimed invention, a process for electroless plating a metal cap barrier on a substrate is disclosed. Copper metallization is formed on the substrate such that the substrate has an exposed top surface of a copper line. The exposed top surface of the copper line is pre-cleaned. The pre-cleaned exposed top surface of the copper line is exposed to an activation solution. The exposed top surface of the copper line of the substrate is then in-situ annealed in an vapor ambient containing a flow of alcohol and carrier gas at a temperature less than 400° C. The metal cap barrier is selectively deposited onto the exposed top surface of the copper line by performing electroless plating.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-4 are schematic, cross-sectional diagrams generally showing the processing steps of copper metallization;

FIG. 5 is a flowchart in accordance with the present invention; and

FIG. 6 is a schematic diagram showing an apparatus for annealing and reducing the conductive layer in ethanol vapor ambient according to this invention.

### DETAILED DESCRIPTION

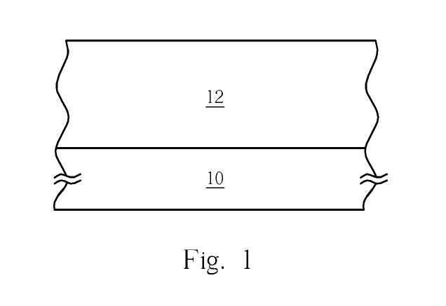

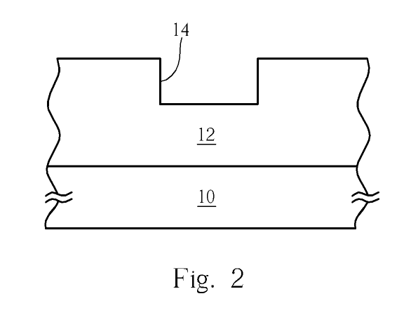

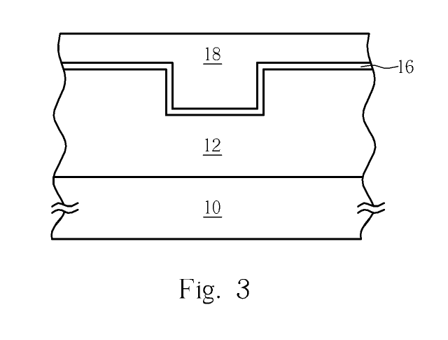

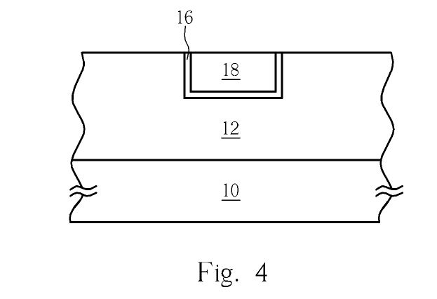

In describing the preferred embodiment of the present invention, reference will be made herein to FIGS. 1-6 of the drawings, wherein like numerals designate like components, areas or regions. Features of the invention are not drawn to scale in the drawings.

FIGS. 1-4 are schematic, cross-sectional diagrams generally showing the processing steps of copper metallization. In accordance with a preferred embodiment of the present invention, a method of forming conductive lines of a semiconductor device comprises depositing an insulating layer 12 such as a low-k dielectric over a substrate 10, patterning the insulating layer 12 with a trench pattern 14 for at least one conductive line, lining the trench pattern 14 with a barrier material 16 such as Ta/TaN, and filling the trench pattern 14 with a conductive material 18. Excess barrier and conductive material are removed from a top surface of the insulating layer 12 by chemical mechanical polishing (CMP).

The low-k dielectric layer described herein may be either organic (e.g., SiLK) or inorganic (e.g., HSQ) and therefore, the term “low-k dielectric” will be used to refer to both organic and inorganic low-k insulators herein. These “low k-dielectric” may be of a porous or non-porous nature. However, embodiments of the present invention are not restricted to low k dielectric insulating layer; the insulating layers described herein may comprise conventional dielectric materials such as SiO₂ or FSG, as examples, as well.

As previously mentioned, copper readily forms copper oxide when exposed to atmospheric conditions. The copper conductive layer 18 is usually pre-cleaned to remove contaminants such as oxides and polymeric residue, and then activated by displacement plating, such as with palladium, prior to depositing a metal cap barrier. The substrate is generally cleaned and activated by multiple steps before depositing the metal cap barrier and transferred to another chamber for depositing a metal cap barrier. The cleaned copper surface is susceptible to further oxidation while being transferred between the cleaning chamber and the deposition chamber, therefore the time the freshly cleaned surfaces are exposed to the atmosphere is critical.

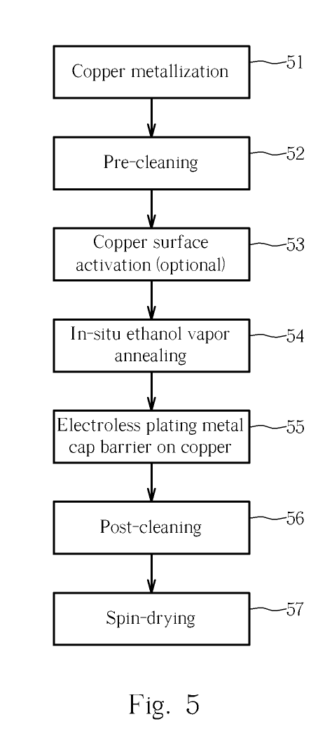

Referring to FIG. 5, a flowchart in accordance with the present invention is illustrated. In one embodiment, a method to deposit a cobalt-containing layer by an electroless deposition process is provided which includes pre-cleaning the conductive layer (Step 52) after the copper metallization process (Step 51), optionally exposing a conductive layer on a substrate to an activation solution to form an activated conductive layer (Step 53), in-situ annealing and reducing the activated conductive layer in alcohol vapor ambient (Step 54), exposing the freshly reduced conductive layer to a plating solution to deposit the cobalt-containing metal cap barrier (Step 55), post-cleaning the capped conductive layer (Step 56), and spin drying the substrate (Step 57).

During the pre-clean (Step 52), a cleaning solution is dispensed across or sprayed on the substrate surface to clean and precondition the surface. The pre-clean process usually includes an acidic pre-clean solution with a pH of about 4 or less, preferably, from about 1.5 to about 3. The pre-clean solution may contain chelator or complexing agent, such as a carboxylic acid or carboxylate, for example, a citrate, oxalic acid, glycine, salts thereof and combinations thereof. In one example, the pre-clean contains about 0.05 M to about 0.5 M of citric acid and optionally up to about 0.25 M of methanesulfonic acid.

In Step 53, prior to the deposition of cobalt-containing alloy, an initiation layer may be formed on the exposed conductive material by displacement plating of a catalytic metal such a palladium, platinum, ruthenium, osmium, rhodium or iridium. Typical procedures for displacement plating of copper with palladium employ dilute aqueous acid solutions of palladium salts such as palladium chloride, palladium nitrate or palladium sulfate. An example of a suitable acidic activation solution is one prepared by addition of about 1 mL of a 10 wt % Pd(NO₃)₂ in 10% nitric acid to 1 L of deionized water. In another example, an activation solution contains about 120 ppm palladium chloride and sufficient hydrochloric acid to provide a pH in a range from about 1.5 to about 3. Substrates to be activated are exposed to the activation solution for about 30 seconds at ambient temperature.

In Step 55, a composition of the plating solution may include a cobalt source in a concentration range from about 5 mM to about 20 mM, a tungsten source in a concentration range from about 0.1 mM to about 5 mM, a hypophosphite source in a concentration range from about 5 mM to about 50 mM, a borane reductant in a concentration range from about 5 mM to about 50 mM, a citrate in a concentration range from about 60 mM to about 200 mM, an alkanolamine in a concentration range from about 50 mM to about 150 mM, boric acid in a concentration range from about 1 mM to about 20 mM, a surfactant in a concentration range of about 50 ppm or less, and a pH adjusting agent at a concentration to maintain a pH from about 7 to about 10. Optionally, the composition may also contain one or more stabilizers in concentrations of about 100 ppm or less.

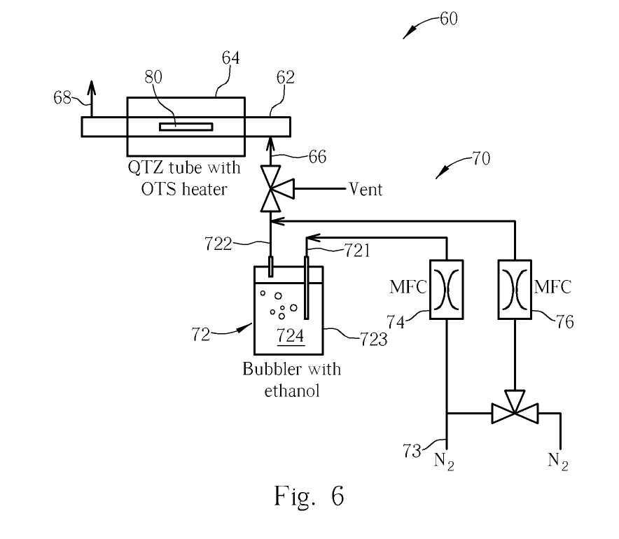

Please refer to FIG. 6. FIG. 6 is a schematic diagram showing an exemplary apparatus for annealing and reducing the conductive layer in alcohol vapor ambient according to this invention. As shown in FIG. 6, in one embodiment, the exemplary apparatus 60 for annealing and reducing the conductive layer in ethanol vapor ambient includes a chamber 62 such as a quartz chamber, a heater 64 such as an OTS heater or a hot plate, and a diluted ethanol vapor supply system 70. A pre-cleaned or activated wafer or semiconductor substrate 80 is positioned inside the chamber 62. The chamber 62 has a gas inlet 66 connected to the diluted ethanol vapor supply system 70 and a gas outlet 68 connected to vent piping.

The diluted ethanol vapor supply system 70 includes a bubbler 72 and a carrier gas source 73 such as nitrogen or helium. The bubbler 72 includes an inlet 721, an outlet 722, and a container 723 for holding alcohol solution such as ethanol solution 724. The temperature of the bubbler 72 is about 18° C. A flow of purging gas controlled by a mass flow controller (MFC) 74 is transferred to the container 723 through the inlet 721. A flow of dilute gas controlled by a MFC 76 is transferred to the outlet 722 for diluting the ethanol vapor purged from the container 723. Preferably, the flow rate of the dilute gas is about three times of the flow rate of the purging gas.

According to one preferred embodiment, the concentration of the diluted ethanol vapor at inlet 66 is about 1.25 wt. %, and the flow rate of the diluted ethanol vapor at inlet 66 is about 0.2-0.8 standard liter per minute (sim). The wafer 80 is heated to a temperature of about 100° C.-400° C., preferably 150° C.-350° C. Under the above-described conditions, the wafer 80 is annealed in a reducing ethanol vapor ambient for a time period of less than 5 minutes.

The above-described apparatus for annealing and reducing the conductive layer in ethanol vapor ambient can be integrated with the electroless plating tool or the apparatus can be a stand-alone tool. If the above-described apparatus for annealing and reducing the conductive layer in ethanol vapor ambient is integrated with the electroless plating tool, the ethanol vapor annealing process is carried out just before the selective deposition of metal cap barrier on copper lines. If the above-described apparatus for annealing and reducing the conductive layer in ethanol vapor ambient is a stand-alone tool, the ethanol vapor annealing process may be carried out before or after the copper surface activation, or before the pre-clean step.

Those skilled in the art will readily observe that numerous modifications and alterations of the device and method may be made while retaining the teachings of the invention. Accordingly, the above disclosure should be construed as limited only by the metes and bounds of the appended claims.

1. A process for electroless plating a metal cap barrier on a substrate, comprising the steps of:
performing copper metallization on the substrate such that the substrate has an exposed top surface of a copper line;
pre-cleaning the exposed top surface of the copper line;
activating the pre-cleaned exposed top surface of the copper line to an activation solution;
in-situ annealing the exposed top surface of the copper line of the substrate in an vapor ambient containing a flow of alcohol and carrier gas at a temperature less than 400° C. within an electroless plating tool; and
after in-situ annealing the exposed top surface of the copper line, selectively depositing the metal cap barrier onto the exposed top surface of the copper line by performing electroless plating in-situ within the electroless plating tool.

2. The process for electroless plating a metal cap barrier on a substrate according to claim 1 wherein the copper metallization comprises the following steps:
depositing a dielectric on the substrate;
forming a trench in the dielectric;
lining interior surface of the trench with a layer of barrier material;
filling the trench with copper; and
chemical mechanical polishing excess copper outside the trench to form the exposed top surface of the copper line.

3. The process for electroless plating a metal cap barrier on a substrate according to claim 1 wherein the step of pre-cleaning the exposed top surface of the copper line uses a pre-clean solution with a pH of about 4 or less.

4. The process for electroless plating a metal cap barrier on a substrate according to claim 1 wherein the activation solution contains catalytic metal comprising palladium, platinum, ruthenium, osmium, rhodium and iridium.

5. The process for electroless plating a metal cap barrier on a substrate according to claim 1 wherein the alcohol includes ethanol.

6. The process for electroless plating a metal cap barrier on a substrate according to claim 1 the alcohol is provided by a bubbler.

7. The process for electroless plating a metal cap barrier on a substrate according to claim 1 wherein the carrier gas includes nitrogen and helium.

8. The process for electroless plating a metal cap barrier on a substrate according to claim 1 wherein the step of in-situ annealing the exposed top surface of the copper line of the substrate is carried out at a temperature of 150-350° C. for a time period of less than 5 minutes.

9. A process for electroless plating a metal cap barrier on a substrate, comprising the steps of:
performing copper metallization on the substrate such that the substrate has an exposed top surface of a copper line;
pre-cleaning the exposed top surface of the copper line;
vapor annealing the exposed top surface of the copper line of the substrate in a reducing ambient containing a flow of alcohol and carrier gas at a temperature less than 400° C. within an electroless plating tool; and
selectively depositing the metal cap barrier onto the exposed top surface of the copper line by performing electroless plating in-situ within the electroless plating tool.

10. The process for electroless plating a metal cap barrier on a substrate according to claim 9 wherein the copper metallization comprises the following steps:
depositing a dielectric on the substrate;
forming a trench in the dielectric;
lining interior surface of the trench with a layer of barrier material;
filling the trench with copper; and
chemical mechanical polishing excess copper outside the trench to form the exposed top surface of the copper line.

11. The process for electroless plating a metal cap barrier on a substrate according to claim 9 wherein the step of pre-cleaning the exposed top surface of the copper line uses a pre-clean solution with a pH of about 4 or less.

12. The process for electroless plating a metal cap barrier on a substrate according to claim 9 wherein the alcohol includes ethanol.

13. The process for electroless plating a metal cap barrier on a substrate according to claim 9 wherein the alcohol is provided by a bubbler.

14. The process for electroless plating a metal cap barrier on a substrate according to claim 9 wherein the carrier gas includes nitrogen and helium.

15. The process for electroless plating a metal cap barrier on a substrate according to claim 9 wherein the step of vapor annealing the exposed top surface of the copper line of the substrate is carried out at a temperature of 150-350° C. for a time period of less than 5 minutes.
